(19) United States
(12) Patent Application Publication
(10) Pub. No.: US 2023/0154915 A1
(43) Pub. Date: May 18, 2023

(54) DUAL RESISTOR INTEGRATION

(71) Applicant: Texas Instruments Incorporated, Dallas, TX (US)

(72) Inventors: Bhaskar Srinivasan, Allen, TX (US); Qi-Zhong Hong, Richardson, TX (US); Jarvis Benjamin Jacobs, Murphy, TX (US)

(21) Appl. No.: 17/525,167

(22) Filed: Nov. 12, 2021

(51) Int. Cl. H01L 27/01; H01L 23/522; H01L 27/13

(52) U.S. Cl. CPC H01L 27/016; H01L 23/5228; H01L 27/13; H01L 27/1207

(57) ABSTRACT

An electronic device includes a first thin film resistor and a second thin film resistor above a dielectric layer that extends in a first plane of orthogonal first and second directions, the first resistor has three portions with the second portion extending between the first and third portions, and a recess etched into the top side of the second portion by a controlled etch process to increase the sheet resistance of the first resistor for dual thin film resistor integration.

### BACKGROUND

Integration of thin film resistors of different sheet resistances in packaged electronic devices provides flexibility in integrated circuit design. However, integrating high and lower sheet resistance components during wafer fabrication involves separate deposition, patterning, cleaning and possibly annealing of resistor films in different metallization levels. This increases manufacturing costs. In addition, sheet resistance non-uniformity across a processed wafer is a problem that inhibits design goals with respect to controlling absolute sheet resistance.

### SUMMARY

In one aspect, an electronic device includes a semiconductor surface layer, a dielectric layer, a first resistor, and a second resistor. The dielectric layer is above the semiconductor surface layer and the dielectric layer has a side extending in a first plane of orthogonal first and second directions. The first resistor has opposite first and second sides and a recess. The first side of the first resistor is above and facing the side of the dielectric layer, and the second side of the first resistor extends in a second plane of the first and second directions. The first and second planes are spaced apart along a third direction that is orthogonal to the first and second directions. The recess extends into the second side of the first resistor along the third direction. The second resistor has opposite first and second sides and is spaced apart from the first resistor along one of the first and second directions. The first side of the second resistor is above and facing the side of the dielectric layer, and the second side of the second resistor extends in the second plane.

In another aspect, a resistor includes a patterned film with opposite first and second sides, a first portion, a second portion, a third portion, and a recess. The first side extends in a plane of orthogonal first and second directions, and the second portion extends between the first and third portions along the first direction. The recess extends into the second side of the second portion along a third direction that is orthogonal to the first and second directions.

In a further aspect, a method of fabricating an electronic device includes forming a film above a dielectric layer, patterning the film to define first and second resistors, and etching a portion of the first resistor to create a recess in a side of the first resistor.

### BRIEF DESCRIPTION OF THE DRAWINGS

FIG. 1 is a partial sectional side elevation view of an electronic device with dual integrated resistors.

FIG. 2 is a flow diagram of a method of fabricating an electronic device.

FIGS. 3-14 illustrate the electronic device of FIG. 1 undergoing fabrication processing according to the method of FIG. 2.

FIGS. 15 and 16 show top views of deposited thin film resistor material having different levels of sheet resistance nonuniformity.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating.

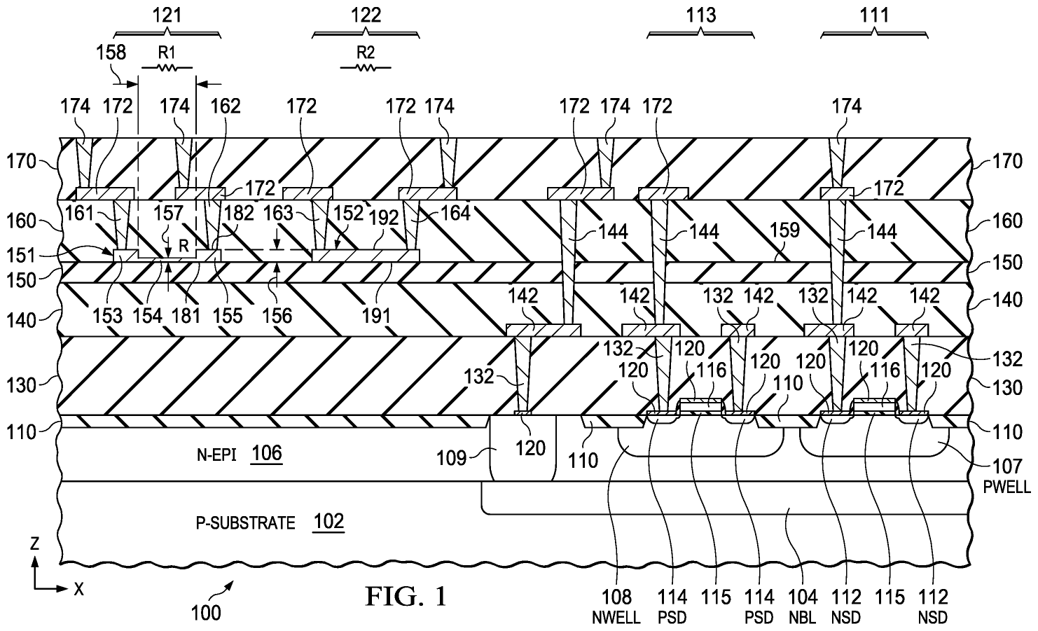

FIG. 1 shows an electronic device 100 that includes integrated thin film resistors having different sheet resistance films fabricated in the same metallization layer or level, along with other circuit components, such as transistors fabricated on or in a semiconductor surface layer. The electronic device 100 in one example is an integrated circuit product, only a portion of which is shown in FIG. 1. The electronic device 100 includes electronic components, such as transistors, resistors, capacitors (not shown) fabricated on or in a semiconductor structure of a starting wafer, which is subsequently separated or singulated into individual semiconductor dies that are separately packaged to produce integrated circuit products.

The electronic device 100 includes a semiconductor structure having a semiconductor substrate 102, a buried layer 104 in a portion of the semiconductor substrate 102, a semiconductor surface layer 106 with an p-doped well or region 107 (e.g., labeled “P-WELL”), an n-doped well or region 108 (e.g., labeled “N-WELL”), an upper or top side and a deep doped region 109. Shallow trench isolation (STI) structures 110 extend into corresponding portions of the top side of the semiconductor surface layer 106. In one example, the shallow trench isolation 110 structures are or include a dielectric material such as silicon dioxide (SiO₂) on or in the semiconductor surface layer 106, for example, SiO₂ deposited into previously formed trenches that extend into the semiconductor surface layer 106 during fabrication of the electronic device 100.

The semiconductor substrate 102 in one example is a silicon or silicon on insulator (SOI) structure that includes majority carrier dopants of a first conductivity type. The buried layer 104 extends in a portion of the semiconductor substrate 102 and includes majority carrier dopants of a second conductivity type. In the illustrated implementation, the first conductivity type is P, the second conductivity type is N, the semiconductor substrate 102 is labeled “P-SUBSTRATE”, and the buried layer 104 is an N-type buried layer labeled “NBL”. In another implementation (not shown), the first conductivity type is N, and the second conductivity type is P.

The semiconductor surface layer 106 in the illustrated example is or includes epitaxial silicon. In one example, the epitaxial silicon has majority carrier dopants of the second conductivity type and is labeled “N-EPI” in the drawings. Alternatively, semiconductor surface layer 106 may have majority carrier dopants of the first conductivity type in which case PWELL 107 can, in some cases, be omitted. The deep doped region 109 includes majority carrier dopants of the second conductivity type. The deep doped region 109 extends from the semiconductor surface layer 106 to the buried layer 104.

The electronic device 100 includes an optional n-channel field effect transistor 111 (e.g., FET or NMOS) with source/drain implanted portions 112 (e.g., a first implanted region) of the semiconductor surface layer 106 along the top side in the p-doped well 107. The implanted portions 112 include majority carrier dopants of the second conductivity type (e.g., labeled “NSD”). The electronic device 100 also includes an optional p-channel FET 113 (e.g., PMOS) having source/drain implanted portions 114 along the top side of the semiconductor surface layer 106 in the n-doped well 108, which include majority carrier dopants of the first conductivity type (e.g., labeled “PSD”). The individual transistors 111 and 113 each have gate dielectric (e.g., gate oxide) layer 115 formed over a channel region laterally between the respective source/drain implanted portions 112 and 114, as well as a doped polysilicon gate electrode 116 on the gate dielectric 115. The transistors 111 and 113 also include metal silicide structures 120 that extend over and provide electrical connection to the source/drain implanted portions 112, 114 and the gate electrodes 116.

The electronic device 100 includes a multilevel metallization structure, only a portion of which is shown in the drawings, with a first thin film resistor 121 and a second thin film resistor 122 formed in the same layer or level of the metallization structure. The first resistor 121 is schematically shown as a resistor labeled “R1” in FIG. 1 and the second resistor 122 is schematically shown as a resistor labeled “R2”. A dielectric layer 130 (e.g., a pre-metal dielectric layer labeled “PMD” in the drawings) extends on or over the shallow trench isolation structure 110, the transistors 111 and 113, and portions of the top side of the semiconductor surface layer 106. In one example, the first dielectric layer is or includes SiO₂. The dielectric layer 130 includes conductive contacts 132 (e.g., tungsten) that extend through the dielectric layer 130 to form electrical contacts to the transistors 111 and 113.

The multilevel metallization structure also includes another dielectric layer 140 (e.g., SiO₂), referred to herein as an interlayer or interlevel dielectric (ILD) layer (e.g., labeled “ILD”). The dielectric layer 140 in one example has a thickness of approximately 4000-8000 Å along the third direction Z. The dielectric layer 140 includes conductive routing structures 142, such as traces or lines of a first metallization layer (e.g., labeled “M1”). In one example, the conductive routing structures 142 are or include copper or aluminum or other conductive metal. The second dielectric layer 140 includes conductive vias 144 that are or include tungsten, copper or aluminum or other conductive metal. In one example, one or more conductive vias 144 contact respective ones of the conductive routing structures 142 through the dielectric layer 140 and through further dielectric layers above the dielectric layer 140.

The electronic device 100 includes a dielectric layer 150 above the semiconductor surface layer 102. The dielectric layer 150 has an upper or top side 159 that extends in a first plane of orthogonal first and second directions X and Y, where the second direction Y extends into the page in the orientation shown in FIG. 1 and the other side elevation view drawings. The dielectric layer 150 in one example is formed above the dielectric layers 130 and 140, and directly on and contacting the top side of the dielectric layer 140. In another example, one or more additional dielectric layers (not shown) extend between the dielectric layer 150 and the semiconductor surface layer 102. In one example, the dielectric layer 150 is or includes SiO₂, such as tetraethyl orthosilicate having a thickness of approximately 500 Å (e.g., also referred to as tetraethoxysilane, and labeled “TEOS” in FIG. 1).

The first resistor 121 includes a patterned first thin film resistor structure 151 and the second resistor 122 includes a patterned second thin film structure 152 that is spaced apart from the first thin film resistor structure 151. In one example, the patterned first and second thin film resistor structure 151 and 152 are or include silicon-chromium (SiCr) that extend on the top side 159 of the dielectric layer 150. The first thin film resistor structure 151 has a first portion 153, a second portion 154, and a third portion 155. The second portion 154 of the first thin film resistor structure 151 extends between the first and third portions 153 and 155 along the first direction X in the orientation shown in FIG. 1. The first and third portions 153 and 155 of the first resistor 121 and the second resistor 122 have substantially equal first thicknesses 156 along the third direction Z.

The first resistor 121 has a recess R that extends into the top side of the second portion 154 of the first thin film resistor structure 151. The recessed second portion 154 has a second thickness 157 along the third direction Z. The first thicknesses 156 are greater than the second thickness 157. The recessed second portion 154 of the first thin film resistor structure 151 has a lateral length 158 along the first direction X. In one example, the lateral length 158 is greater than the second thickness 157. The first thickness 156 in one example is 200 Å or more, and the second thickness 157 is 100 Å or less. In these or other examples, the first thickness is 200 Å or more and 500 Å or less, such as 200 Å to 400 Å (e.g., approximately 350 Å). In these or other examples, the second thickness 157 is 20 Å to 100 Å. In certain implementations, the selective formation of recessed portions in one or more first resistors and formation of one or more other (e.g., second) resistors facilitates precise control of the relative resistivities of the first and second resistors, for example, having sheet resistance ratios of 2 to 30 or more, such as 3.5 to 25, or 4 to 20. In combination with control of the X-Y area and shape of the resistor structures, the resistances R1 and R2 of the respective first and second resistors 121 and 122 can be tailored for a specific circuit design with improved precision and uniformity.

The electronic device 100 further includes a second dielectric layer 160 above the dielectric layer 150, the first resistor 121, and the second resistor 122. The dielectric layer 160 in one example is or includes SiO₂ with a thickness of approximately 3000 Å to 3700 Å along the third direction Z. In the illustrated example, the conductive vias 144 extend through the dielectric layers 140, 150, and 160 as shown in FIG. 1. The electronic device 100 also includes conductive contacts 161-164 (e.g., vias) that extend through the second dielectric layer 160 to respective portions of the first and second thin film resistor structures 151 and 152. The conductive vias 161-164 in one example are or include tungsten, copper or aluminum or other conductive metal.

A conductive first contact 161 extends through the second dielectric layer 160 along the third direction Z and contacts the first portion 153 of the first resistor 121. A conductive second contact 162 extends through the second dielectric layer 160 along the third direction Z and contacts the third portion 155 of the first resistor 121. The second contact 162 is spaced apart from the first contact 161 along the first direction X. A conductive third contact 163 extends through the second dielectric layer 160 along the third direction Z and contacts a portion of the second resistor 122. In addition, a conductive fourth contact 164 in this example extends through the second dielectric layer 160 along the third direction Z and contacts another portion of the second resistor 122. The fourth contact 164 is spaced apart from the third contact 163 along the first direction X.

The multilayer metallization structure in the electronic device 100 also includes a further dielectric layer 170 (e.g., an ILD layer) that extends above (e.g., directly on) the top side of the dielectric layer 160. The dielectric layer 170 in one example is or includes SiO₂ with a thickness of approximately 6000 Å to 12000 Å along the third direction Z. The multilayer metallization structure can include further levels (not shown) in this or another example. In further implementations, the multilayer metallization structure includes fewer layers or levels. The dielectric layer 170 includes conductive routing structures 172, such as traces or lines of a second metallization layer (e.g., labeled “M2”). In one example, the conductive routing structures 172 are or include copper or aluminum or other conductive metal. The dielectric layer 170 also has conductive vias 174 that are or include tungsten, copper or aluminum or other conductive metal.

As further shown in FIG. 1, the first resistor 121 has opposite first and second (e.g., bottom and top) sides 181 and 182. The first side 181 of the first resistor 121 is above and faces the side 159 of the dielectric layer 150. The second side 182 of the first resistor 121 (the top sides of the non-recessed portions 153 and 155) extends in a second plane of the first and second directions X and Y. The first and second planes are spaced apart from one another along the third direction Z. The recess R extends into the second side 182 of the first resistor 121 along the third direction Z. In the illustrated example, the second portion 154 of the first resistor 121 forms the bottom of the recess R and has a length 158 along the first direction X. The second resistor 122 has opposite first and second (e.g., bottom and top) sides 191 and 192, respectively. The second resistor 122 is spaced apart from the first resistor 121 along one of the first and second directions X and/or Y. The first side 191 of the second resistor 122 is above and faces the top side 159 of the dielectric layer 150. The second side 192 of the second resistor 122 extends in the second plane of the first and second directions X and Y.

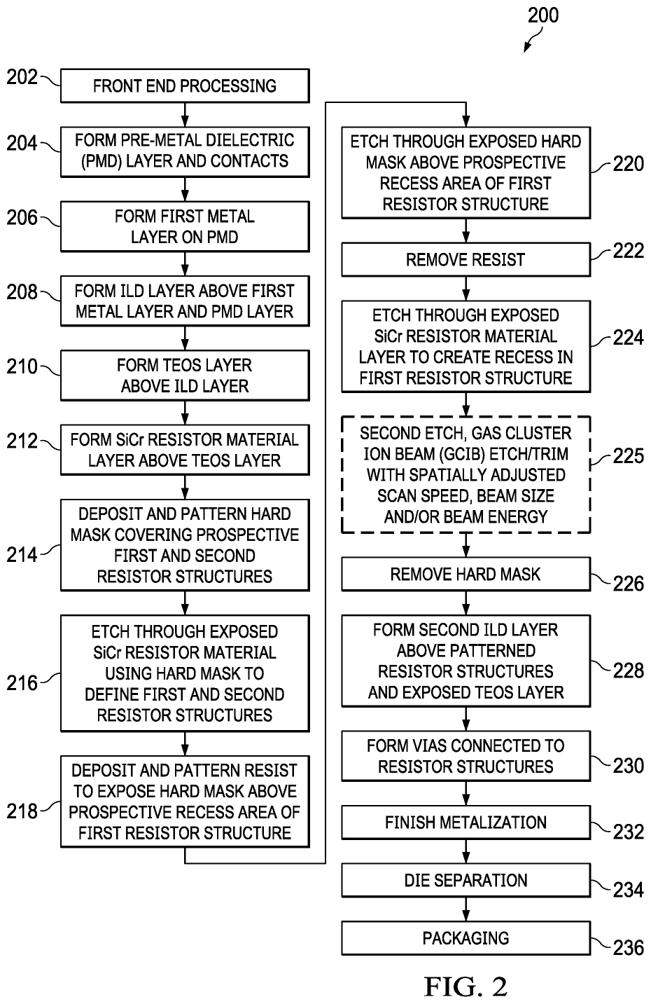

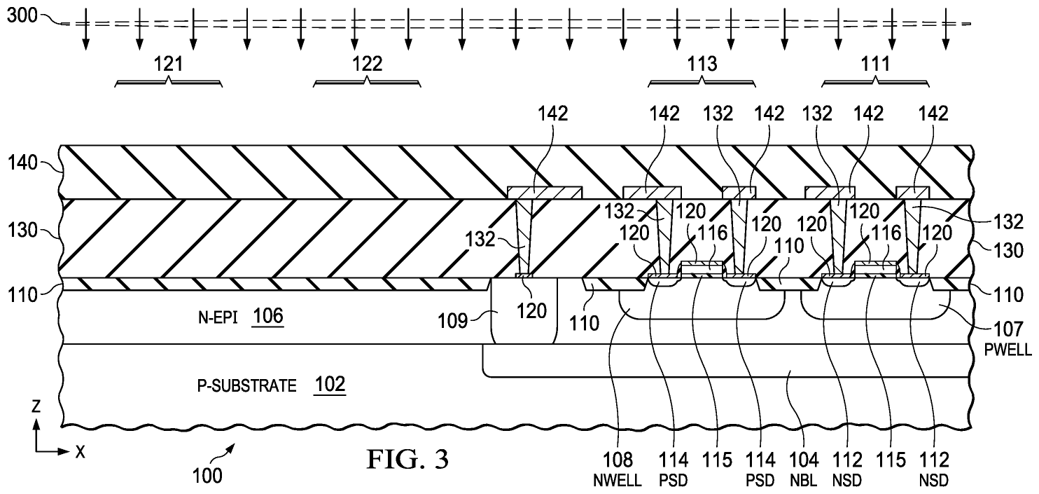

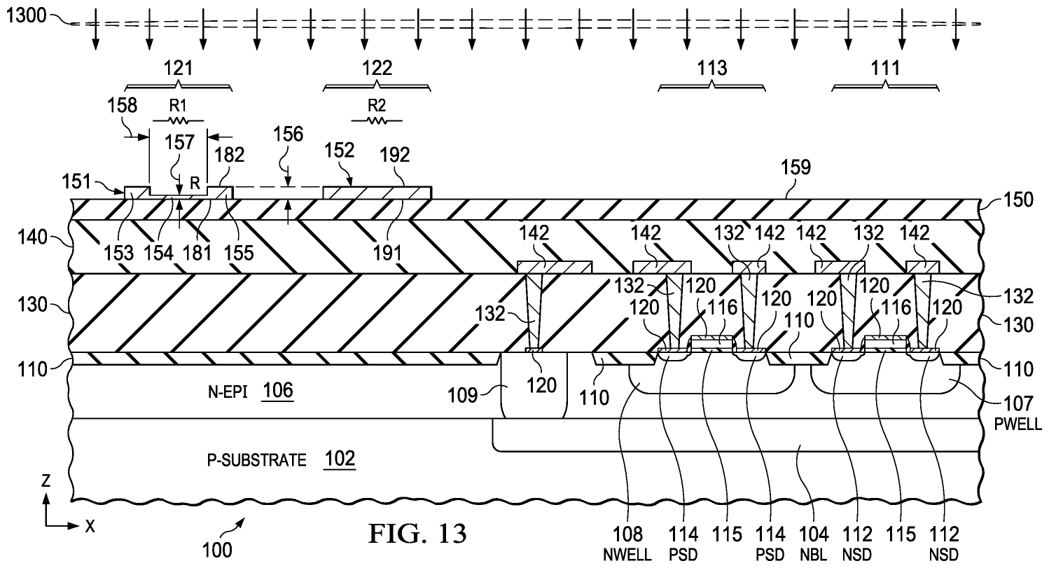

Referring also to FIGS. 2-24, FIG. 2 shows a method 200 for making an electronic device and for making one or more thin film resistors in an electronic device. FIGS. 3-14 show the electronic device 100 of FIG. 1 at various stages of fabrication according to the method 200. The method 200 begins in FIG. 2 with a starting wafer, such as a silicon wafer 102 or a silicon on insulator wafer that includes majority carrier dopants of a first conductivity type (e.g., P in the illustrated example).

The method 200 includes front end processing at 202, including transistor fabrication, isolation (e.g., STI) structure formation, and a pre-metal dielectric (PMD) layer is formed at 204 along with the PMD contacts (e.g., PMD layer 130 and contacts 132 in FIG. 3. At 206 in FIG. 2, a first metal layer (e.g., M1) is deposited on the PMD layer 130 and the metal layer is patterned to form the conductive routing structures 142 shown in FIG. 3. The first ILD layer is formed at 208 over the first metal layer features 142 and the PMD dielectric layer 130 by a deposition process 300 as shown in FIG. 3.

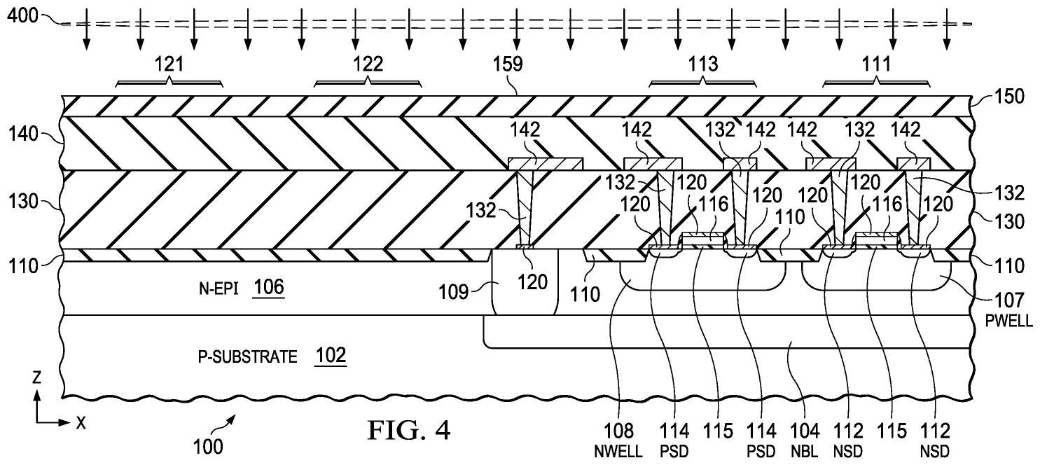

The method 200 continues at 210 with forming the dielectric layer 150. FIG. 4 shows one example, in which a TEOS deposition process 400 is performed that forms the dielectric layer 150 (e.g., SiO₂) to a thickness of approximately 500 Å directly on and contacting the top side of the dielectric layer 140. The dielectric layer 150 in one example includes the generally planar top side 159 that extends in the first plane of the first and second directions X and Y as described above in connection with FIG. 1.

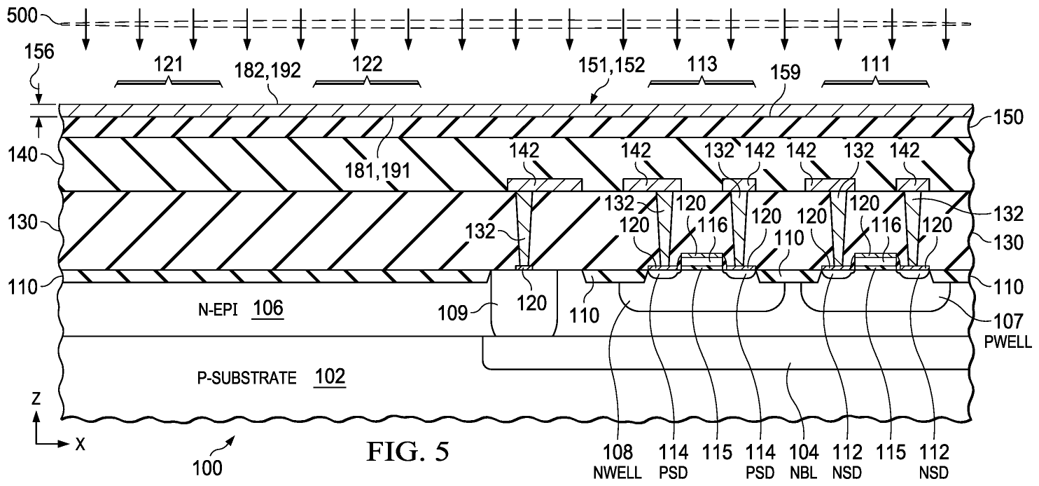

At 212 in FIG. 2, the method 200 also includes forming a film 151, 152 above a dielectric layer 150. FIG. 5 shows one example, in which a sputter deposition process 500 is performed that deposits the film 151, 152 that is or includes SiCr on the dielectric layer 150 above the dielectric layer 150 to the first thickness 156 of 200 Å or more and 500 Å or less, such as 200 Å to 400 Å, for example, approximately 350 Å to 400 Å. In one example, the deposited film 151, 152 has a nominal sheet resistance Rs of 100 Ω/square for SiCr film of thickness 156 of approximately 350 Å, and the deposited film 151, 152 has a sheet resistance nonuniformity six sigma of approximately 12% to 15%.

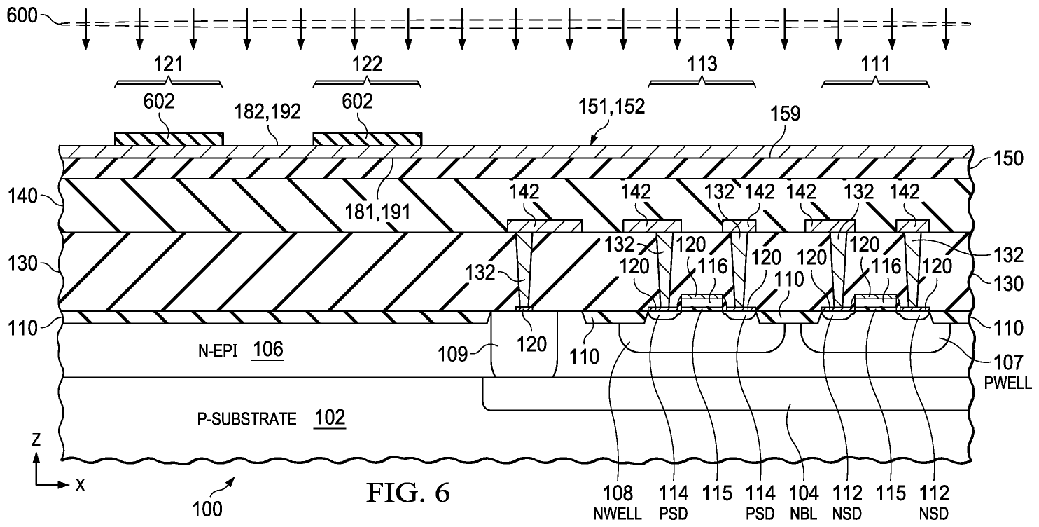

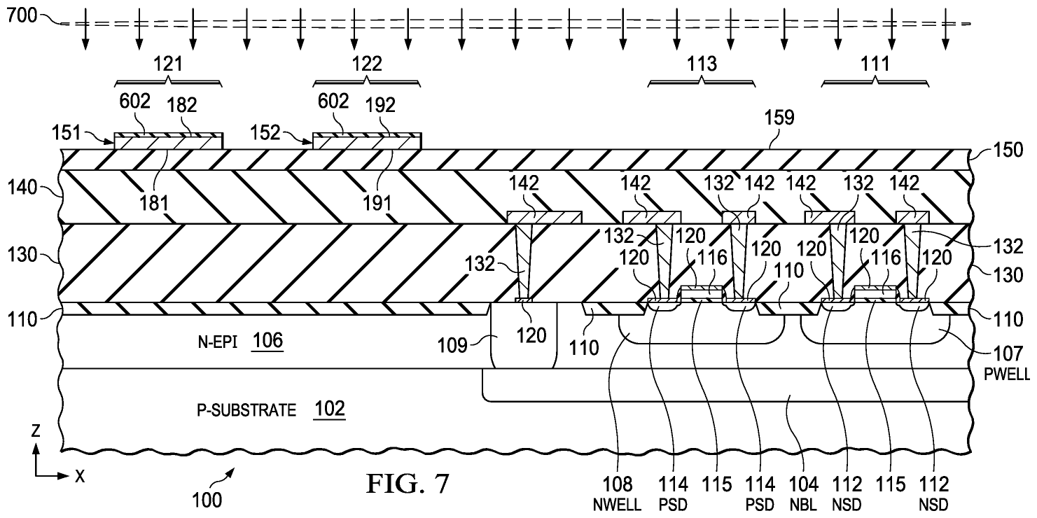

At 214 and 216 in FIG. 2, the example method 200 also includes patterning the film 151, 152 to define the first and second resistors 121 and 122 by defining the patterned first thin film resistor structure 151 and the patterned second thin film structure 152. FIG. 6 shows one example, in which a process 600 is performed that deposits and patterns a hard mask 602 to cover the prospective first thin film resistor structure 151 and the prospective second thin film structure 152. At 216, the exposed film 151, 152 is etched using the hard mask 602 to define the patterned first thin film resistor structure 151 and the patterned second thin film structure 152. FIG. 7 shows one example, in which an etch process 700 is performed with the hard mask 602 that etches the exposed portions of the deposited film 151, 152 and leaves the patterned first and second thin film structures of the respective first and second resistors 121 and 122.

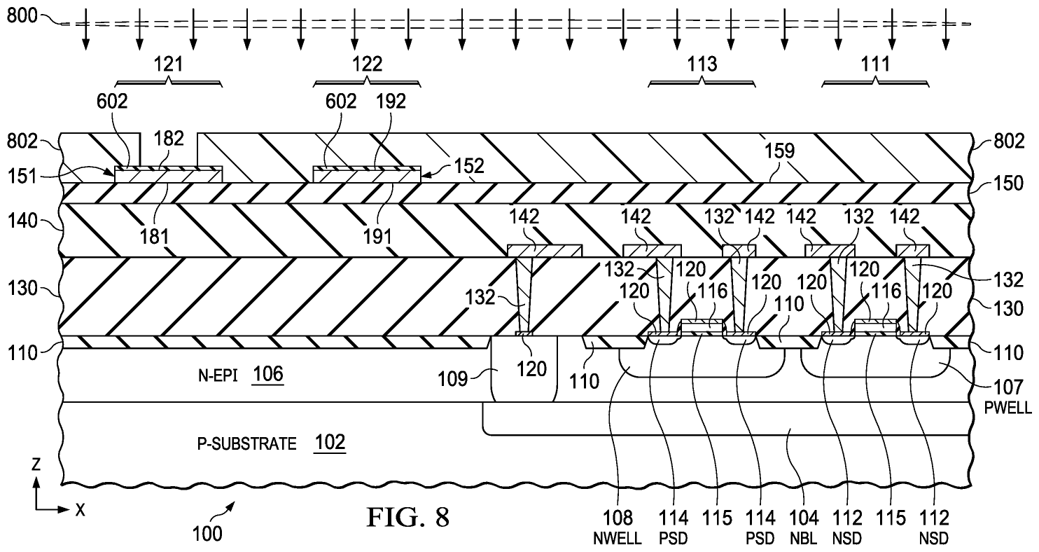

The method 200 continues at 218 in FIG. 2, with depositing and patterning a resist to expose a portion of the hard mask above the prospective recess of the first resistor 121. FIG. 8 shows one example, in which a process 800 is performed that deposits and patterns a resist layer 802 to expose the remaining hard mask 602 above the prospective second portion of the first resistor 121 and cover the second resistor 122 and the first and third portions of the first resistor 121.

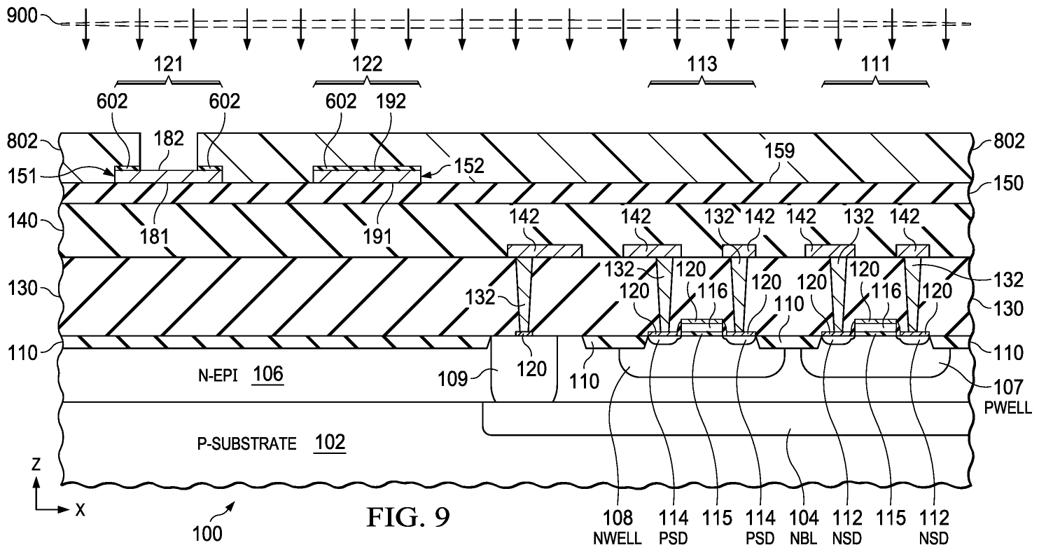

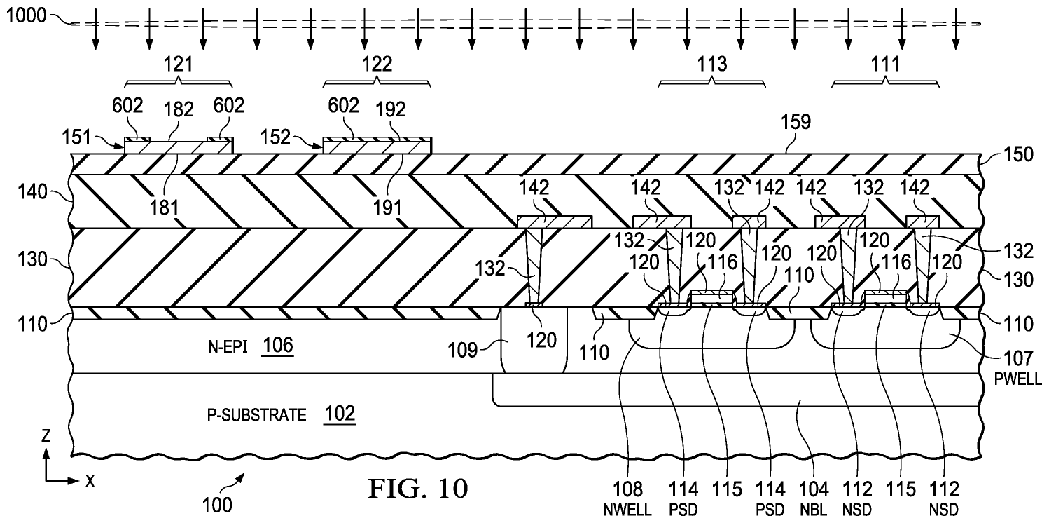

At 220 in FIG. 2, the method 200 continues with etching through the exposed hard mask 602 to expose the prospective second portion of the first resistor 121. FIG. 9 shows one example, in which an etch process 900 is performed using the resist 802 as a mask. The etch process 900 etches through the exposed hard mask 602 to expose the top side 182 of the prospective second portion of the first resistor 121. The resist 802 is then removed at 222 using a process 1000 as shown in FIG. 10.

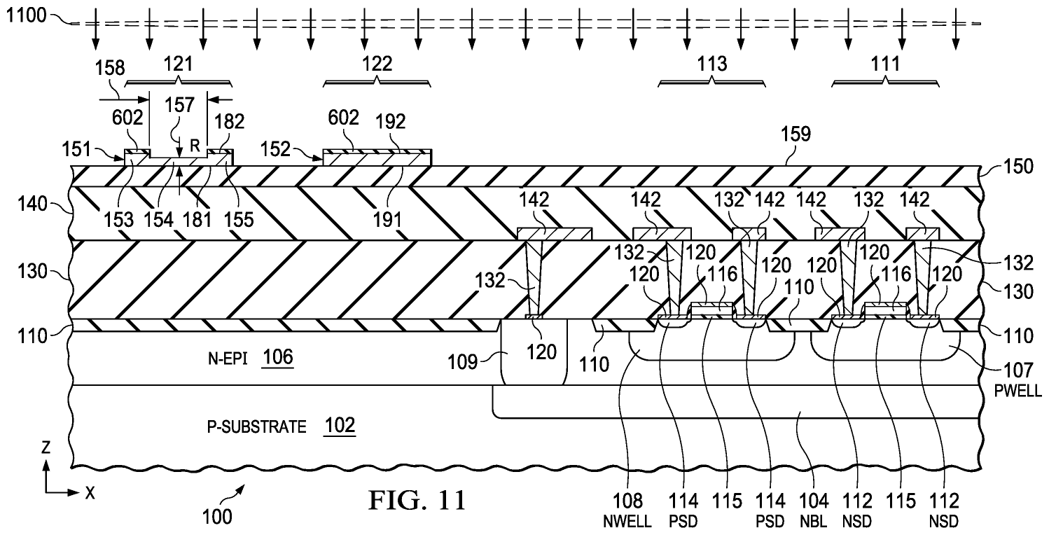

The method 200 continues at 224 with etching some of the second portion 154 of the first resistor 121 to create the recess R in the upper or top side 182 of the first resistor 121. FIG. 11 shows one example, in which a reactive ion etch (RIE) also referred to as ion beam etching (IBE)) process 1100 is performed that etches some of the top side of the second portion 154 of the first thin film resistor structure 151. In one example, the first etch process 1100 uses a beam current of 20-100 mA, a beam energy of 1000-2000 eV, and a total beam power of approximately 20-200 W.

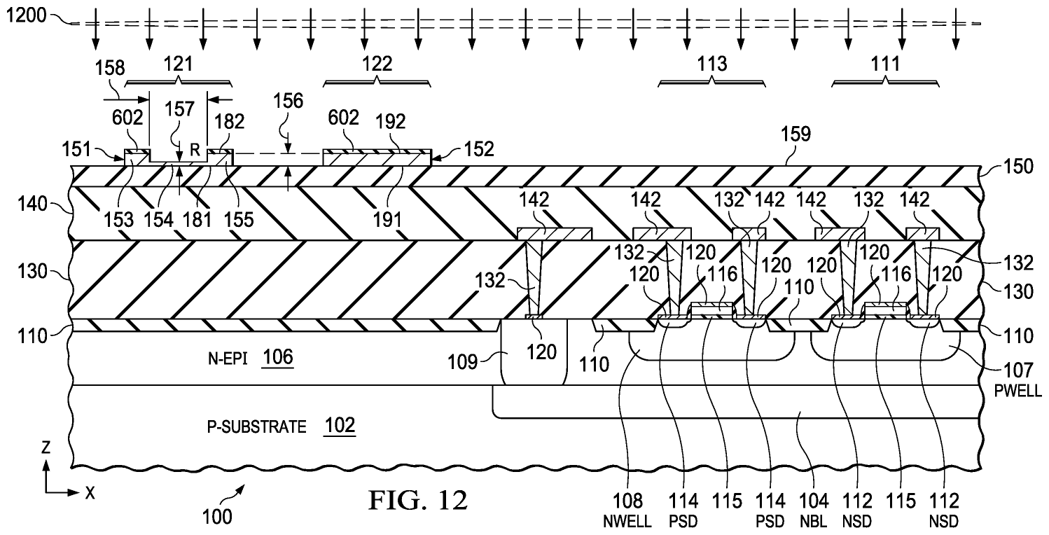

A single etch can be used at 224 in one example, or multiple etch steps can be implemented to create the recess R. In the illustrated example, the RIE etch process 1100 is performed at 224 in FIG. 2 to remove an initial top portion of the film 151 as shown in FIG. 11 and to reduce the thickness of the second portion 154 to an intermediate thickness. In one implementation, a second etch is performed at 225 to set the final second thickness 157 of the second portion 154 of the first resistor 121. FIG. 12 shows one example, in which a second etch process 1200 is performed that further etches the exposed second portion 154 to set the final second thickness 157 of the second portion 154 of the first resistor 121. The etch process or processes at 224 and/or 225 provide a manufacturing trim to set the second thickness 156, to set the effective sheet resistance of the second portion 154 of the first resistor 121, and to set the final resistance R1 of the first resistor 121. In one example, the remaining second portion 154 of the first resistor 121 has a nominal sheet resistance 1000 Ω/square for a SiCr film of final second thickness 157 of approximately 32 Å and a sheet resistance nonuniformity six sigma of approximately 2% to 3%. In one example, the second etch process 1200 at 225 is a gas cluster ion beam (GCIB) etch/trim process with one or more controlled parameters (e.g., beam current energy, scan speed, etc.) to finish the recess R (e.g., the final second thickness 157) for example, 100 Å or less, such as 20 Å to 50 Å, e.g., about 35 Å. In one or more implementations, the example GCIB process 1200, the beam current is approximately 0.1 mA, the beam energy is 30-60 eV, and the total beam power is approximately 5 W. The process 1200 in one example uses one or more gases selected from NF₃, O₂, CF₄, CHF₃, N₂, and Ar, and the etch process 1200 includes cluster formation driven by adiabatic cooling.

In one implementation, one or both of the etch processes 1100 and/or 1200 include a spatially adjusted etching by varying one or more etch process parameters according to the location (e.g., in the X and Y directions) to improve sheet resistance uniformity across wafer. One implementation includes establishing a profile of sheet resistance linearity vs. removed thickness (trim), for example, by measuring deposited film thickness of one or more test wafers following blanket deposition of the SiCr film 151, 152 on a TEOS oxide layer. During one or both the etch processes 1100 and/or 1200, one or more etch parameters are spatially controlled or adjusted to counteract the nonuniformity identified in the test wafers, for example, using interpolation between tested X,Y points to improve starting nonuniformity (e.g., six sigma ˜10% to 15%) to a final nonuniformity (e.g., six sigma ˜2% to 3%). In one example, one or both the etch processes 1100 and/or 1200 use a sharp beam profile with spatially determined raster scan energy/speed/beam thickness profile to counteract deposited thickness nonuniformity, for example, according to a created scanner speed map used in high precision final GCIB etch/trim processing at 225.

Certain implementations can advantageously provide a 20 to 30× improvement in range or sigma of final film thickness 157. The described examples can provide temperature coefficient of resistance (TCR) performance comparable to baseline thin film resistor fabrication techniques, along with resistor component head resistance comparable to the baseline, as well as resistor matching results (e.g., GCIB using NF₃ trim splits similar to baseline travel wafer (moving wafer itself causes increased mismatch), where Ar and/or O₂ trim has slightly higher matching performance, in combination with reduced production costs for dual resistor integration in a single metallization layer or level (e.g., thin film resistors having two or more controlled sheet resistances) with fewer masks, deposition steps and cleaning steps) compared to integration in different metallization levels. The following table shows example resistor matching error data normalized to matching in a baseline travel wafer for a baseline wafer, the baseline travel wafer that has been transported (e.g., travelled), and four different wafers processed according to the illustrated example with spatial beam energy profile control during trim etching, illustrating comparable matching performance to the baseline, in addition to the product cost reduction benefits and nonuniformity reduction.

| | Matching |
|---|---|
| | (normalized |
| | to baseline |
| Splits | travel wafer |
| BL_b1 | 0.850 |
| BL_travel | 1.000 |
| BL_NF₃ trim | 1.003 |
| BL 10% thick-NF₃ trim | 1.006 |
| BL 10% thick-AR trim | 1.024 |
| BL 10% thick-O₂ trim | 1.050 |

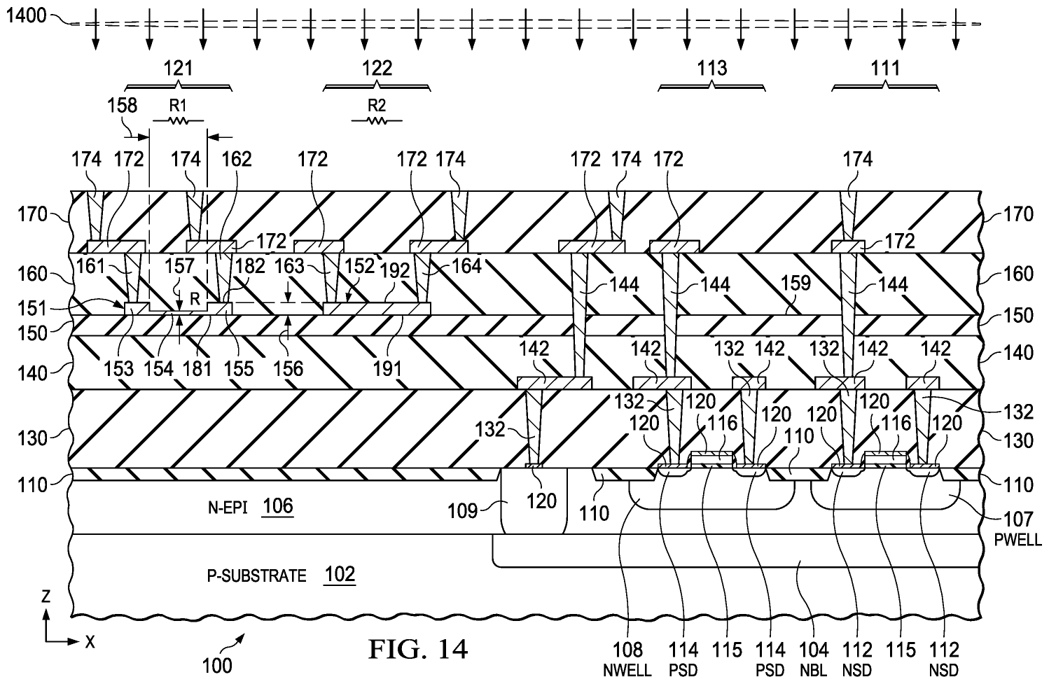

Following the etching at 224 and/or 225, the hard mask is optionally removed at 226, for example, by a stripping or other cleaning process 1300 shown in FIG. 3, and the processed wafer can optionally be treated with O₂ to adjust temperature coefficient of resistance (TCR) for first resistor 121. In another implementation, the hard mask removal at 226 is omitted, and the hard mask is used as an etch stop for etching holes for the vias 161-164. At 228, the method 200 also includes forming the second dielectric layer 160 above the dielectric layer 150, the first resistor 121, and the second resistor 122, as well as forming the conductive vias or contacts 161-164 through the second dielectric layer 160 at 230 to individually contact a portion of a respective one of the first and second resistors 121 and 122, along with fabrication of one or more additional metallization levels or layers at 232 to finish the multilevel metallization structure, shown as the processing 1400 in FIG. 14. The processed wafer undergoes wafer probe testing and individual semiconductor dies are separated or singulated from the wafer at 234 and packaged at 236 in FIG. 2.

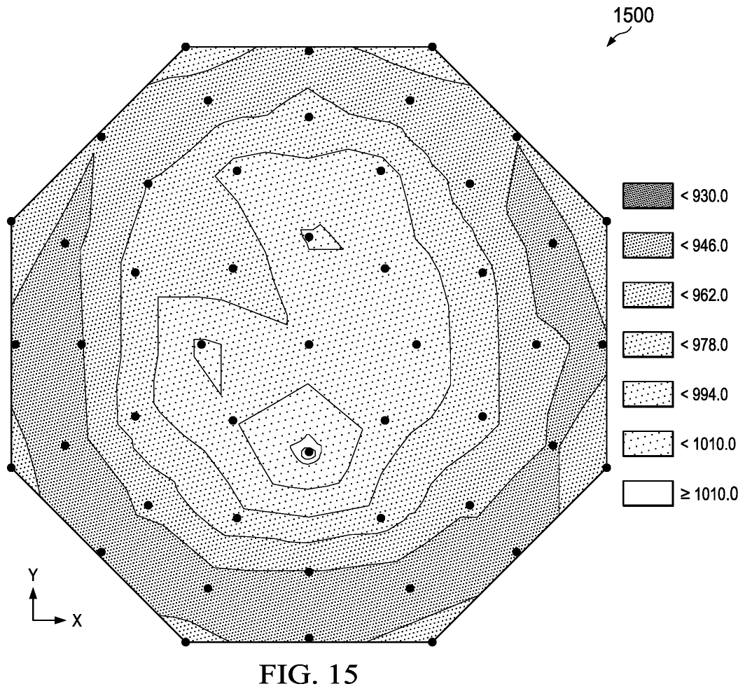

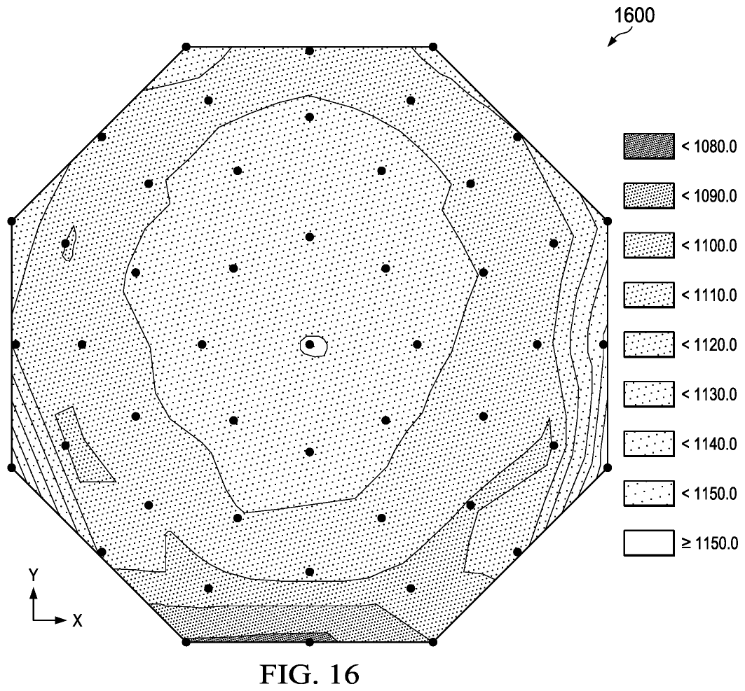

FIGS. 15 and 16 show top views of deposited thin film resistor material having different levels of thickness and sheet resistance nonuniformity. The view 1500 in FIG. 15 shows high nonuniformity without the spatially adjusted trimming of the example method 200. FIG. 16 shows a top view 160 with improved uniformity using the spatially adjusted trimming of the example method 200.

Modifications are possible in the described examples, and other implementations are possible, within the scope of the claims.

What is claimed is:

1. An electronic device, comprising:
a semiconductor surface layer;
a dielectric layer above the semiconductor surface layer, the dielectric layer having a side extending in a first plane of orthogonal first and second directions;
a first resistor having opposite first and second sides and a recess, the first side of the first resistor above and facing the side of the dielectric layer, the second side of the first resistor extending in a second plane of the first and second directions, the first and second planes spaced apart from one another along a third direction that is orthogonal to the first and second directions, the recess extending into the second side of the first resistor along the third direction;
a second resistor having opposite first and second sides, the second resistor spaced apart from the first resistor along one of the first and second directions, the first side of the second resistor above and facing the side of the dielectric layer, the second side of the second resistor extending in the second plane.

2. The electronic device of claim 1, wherein the first resistor has a first portion, a second portion, and a third portion, the second portion extending between the first and third portions along the first direction, and the recess extending into the second side of the second portion of the first resistor.

3. The electronic device of claim 2, wherein:
the first and third portions of the first resistor and the second resistor have substantially equal first thicknesses along the third direction;
the second portion of the first resistor has a second thickness along the third direction; and
the first thicknesses are greater than the second thickness.

4. The electronic device of claim 3, further comprising:
a second dielectric layer above the dielectric layer, the first resistor, and the second resistor;
a conductive first contact extending through the second dielectric layer along the third direction and contacting the first portion of the first resistor;
a conductive second contact extending through the second dielectric layer along the third direction and contacting the third portion of the first resistor, the second contact spaced apart from the first contact along the first direction;
a conductive third contact extending through the second dielectric layer along the third direction and contacting a portion of the second resistor; and
a conductive fourth contact extending through the second dielectric layer along the third direction and contacting another portion of the second resistor, the fourth contact spaced apart from the third contact along the first direction.

5. The electronic device of claim 2, wherein: the first thickness is 200 Å or more, and the second thickness is 100 Å or less.

6. The electronic device of claim 1, further comprising:
a second dielectric layer above the dielectric layer, the first resistor, and the second resistor;
a conductive first contact extending through the second dielectric layer along the third direction and contacting a first portion of the first resistor;
a conductive second contact extending through the second dielectric layer along the third direction and contacting another portion of the first resistor, the second contact spaced apart from the first contact along the first direction;
a conductive third contact extending through the second dielectric layer along the third direction and contacting a portion of the second resistor; and
a conductive fourth contact extending through the second dielectric layer along the third direction and contacting another portion of the second resistor, the fourth contact spaced apart from the third contact along the first direction.

7. The electronic device of claim 1, wherein: the second resistor has a first thickness along the third direction of 200 Å or more, and a recessed portion of the first resistor has a second thickness of 100 Å or less.

8. The electronic device of claim 7, wherein the second thickness is 50 Å or less.

9. The electronic device of claim 1, wherein the first resistor and the second resistor include silicon-chromium.

10. A resistor, comprising:
a patterned film having opposite first and second sides, a first portion, a second portion, a third portion, and a recess;
the first side extending in a plane of orthogonal first and second directions;
the second portion extending between the first and third portions along the first direction;
the recess extending into the second side of the second portion along a third direction that is orthogonal to the first and second directions.

11. The resistor of claim 10, wherein:
the first and third portions have substantially equal first thicknesses along the third direction;
the second portion has a second thickness along the third direction;
the first thickness is 200 Å or more; and
the second thickness is 100 Å or less.

12. The resistor of claim 11, wherein the second thickness is 50 Å or less.

13. The resistor of claim 11, further comprising:
a dielectric layer above the first portion, the second portion, and the third portion;
a conductive first contact extending through the dielectric layer along the third direction and contacting the first portion;
a conductive second contact extending through the dielectric layer along the third direction and contacting the third portion.

14. The resistor of claim 10, further comprising:
a dielectric layer above the first portion, the second portion, and the third portion;
a conductive first contact extending through the dielectric layer along the third direction and contacting the first portion;
a conductive second contact extending through the dielectric layer along the third direction and contacting the third portion.

15. A method of fabricating an electronic device, the method comprising:
forming a film above a dielectric layer;
patterning the film to define first and second resistors; and
etching a portion of the first resistor to create a recess in a side of the first resistor.

16. The method of claim 15, wherein the first resistor has a first portion, a second portion, and a third portion, the second portion extending between the first and third portions along a first direction, and the recess extends into the second portion of the first resistor; the method further comprising:
forming a second dielectric layer above the dielectric layer, the first resistor, and the second resistor;
forming a conductive first contact through the second dielectric layer and contacting the first portion of the first resistor;
forming a conductive second contact through the second dielectric layer and contacting the third portion of the first resistor;
forming a conductive third contact through the second dielectric layer and contacting a portion of the second resistor; and
forming a conductive fourth contact through the second dielectric layer and contacting another portion of the second resistor.

17. The method of claim 15, wherein:
forming the film above the dielectric layer includes performing a sputter deposition process that deposits the film on the dielectric layer to a first thickness of 200 Å or more and 500 Å or less; and
etching the portion of the first resistor to create the recess in the side of the first resistor includes performing an etch process that etches the film in the portion of the first resistor to create the recess having a second thickness of 100 Å or less.

18. The method of claim 17, wherein the etch process etches the film in the portion of the first resistor to create the recess having a second thickness of 20-100 Å.

19. The method of claim 15, wherein etching the portion of the first resistor to create the recess in the side of the first resistor includes:
performing a first etch process that etches the film in the portion of the first resistor to create the recess having an intermediate thickness that is less than a starting thickness of the film; and
performing a second etch process that further etches the film in the portion of the first resistor to create the recess having a final thickness that is less than the intermediate thickness.

20. The method of claim 19, wherein:
the first etch process is a reactive ion etch process; and
the second etch process is a gas cluster ion beam etch/trim process.
